(19) United States
(12) Patent Application Publication
(10) Pub. No.: US 2016/0255747 A1
(43) Pub. Date: Sep. 1, 2016

(54) BONDING STRATEGY FOR LARGE AREA METAL-CLADDED CERAMIC SUBSTRATE

(71) Applicant: GM Global Technology Operations LLC, Detroit, MI (US)

(72) Inventors: VICENTIU GROSU, SAN PEDRO, CA (US); ANDREW A. WERESZCZAK, OAK RIDGE, TN (US)

(21) Appl. No.: 14/633,873

(22) Filed: Feb. 27, 2015

(51) Int. Cl. H05K 7/20

(52) U.S. Cl. CPC H05K 7/20481

(57) ABSTRACT

A number of variations may include a device that may include a first substrate having at least one concentrically ground surface; and a second substrate overlying the first substrate in a hexagonally-arrayed print pattern.

One or more inventions set forth herein was made under

Government Contract No. DE-AC05-000R22725. The government may have certain rights in one or more inventions described herein.

### TECHNICAL FIELD

The field to which the disclosure generally relates includes methods of cladding electronic devices with a metallic layer.

### BACKGROUND

In the operation of power electronic devices, specifically those having a relatively large surface area, approximately two or more square centimeters, it is desirable to have maximum heat transfer, sheer strength, and thermal cycling resistance between any number of adjacent substrates. In some instances, it may be desirable to provide a second substrate comprising a metallic material or metallic paste over a first substrate, wherein the second substrate may be a ceramic or metallic electronic device.

### SUMMARY OF ILLUSTRATIVE VARIATIONS

A number of variations may include a product that may include a first substrate having at least one concentrically ground surface and a second substrate that may overlie the first substrate in a hexagonally-arrayed print pattern.

A number of variations may also include a method that may include providing a first substrate that may include a first surface and a first material, grinding the first surface of the first substrate to provide a concentric-circle pattern that may include radial corrugation channels, and cladding the first surface of the first substrate with a second material by forming a hexagonal pattern of the second material on the first substrate.

A number of variations may include a method that may include providing a first substrate that may include a first surface and a first material. The method may further include grinding the first surface of the first substrate to provide a concentric-circle pattern that may include radial corrugation channels. The method may further include cladding the first surface of the first substrate with a second material that may include a sinterable silver paste by printing a hexagonal pattern of the second material on the first surface of the first substrate wherein the hexagonal pattern may include a plurality of hexagon shaped plates which each may have a surface area of about 86 square millimeters and wherein a plurality of gaps may be disposed between adjacent hexagon shaped plates and may be about 0.5 millimeters in width. The method may further include sintering the second material to form an interconnect between the first material and the second material.

Other illustrative variations within the scope of the invention will become apparent from the detailed description provided hereinafter. It should be understood that the detailed description and enumerated variations, while disclosing optional variations, are intended for purposes of illustration only and are not intended to limit the scope of the invention.

### BRIEF DESCRIPTION OF THE DRAWINGS

Select examples of variations within the scope of the invention will become more fully understood from the detailed description and the accompanying drawings, wherein:

FIG. 1 depicts one variation including a first substrate having a first surface with a concentric-circle pattern;

FIG. 2 depicts one variation including a hexagonal pattern of a second substrate including a second material; and

FIG. 3 depicts one variation including a first substrate having a first surface including a concentric-circle pattern and a hexagonal pattern of a second material.

### DETAILED DESCRIPTION OF ILLUSTRATIVE VARIATIONS

The following description of the variations is merely illustrative in nature and is in no way intended to limit the scope of the invention, its application, or uses. The following description of variants is only illustrative of components, elements, acts, products, and methods considered to be within the scope of the invention and are not in any way intended to limit such scope by what is specifically disclosed or not expressly set forth. The components, elements, acts, products, and methods as described herein may be combined and rearranged other than as expressly described herein and still are considered to be within the scope of the invention.

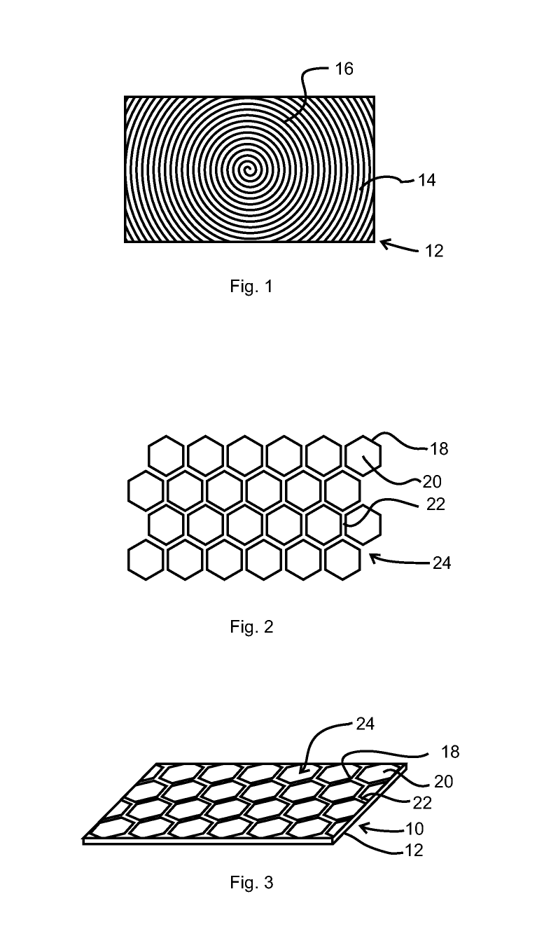

Referring to FIG. 1, a first substrate 12 may include a first surface 14. The first surface 14 may have a concentric-circle pattern 16 formed thereon.

Referring to FIG. 2, a second substrate 24 may include a hexagonal pattern 18 that may include at least one hexagon shaped plate 20. The hexagon shaped plates 20 may include a sinterable silver past. The second substrate 24 may also include a plurality of gaps 22 disposed between adjacent hexagon shaped plates 20.

Referring to FIG. 3, a metal clad substructure 10 may include a first substrate 12 that may include a first surface 14. The metal clad substrate 10 may also include a second substrate 24 that may include a hexagon pattern 18 that may include at least one hexagon shaped plate 20 and a plurality of gaps 22 disposed between adjacent hexagon shaped plates 20. The second substrate 24 may be formed on the first surface 14 of the first substrate 12.

The first substrate 12 may be an electronic device including a metallic or ceramic material. The first substrate 12 may be a component in an electronic device. The first substrate 12 may include a first surface 14 that may include a concentric-circle pattern 16. The concentric-circle pattern 16 may be formed on the first surface 14 through any number of known methods for providing such a pattern. For example, but not limited to, the concentric-circle pattern 16 may be formed on the first surface 14 via mechanical deformation, machining, chemical etching, or other known similar techniques. The concentric-circle pattern 16 may provide radial or concentric corrugation on the first surface 14 that may promote biaxial resistance to in-plane sheer stress.

The second substrate 24 may include a hexagonal pattern 18 that may include at least one hexagon shaped plate 20. A plurality of gaps 22 may be disposed between adjacent hexagon shaped plates 20 such that adjacent hexagon shaped plates 20 are not in contact with one another. The second substrate 24 may include a metallic material such as, but not limited to, a sinterable silver paste. The second substrate 24 may overlie the first substrate 12. The second substrate 24 may be applied to the first surface 14 of the first substrate 12 via a printing method or other similar means of application.

The metal-clad substrate 10 may include a first substrate 12 including a first surface 14 that may have a concentric-circle pattern 16 formed thereon and may further include a second substrate 24 that may include a hexagon pattern 18 that may include at least one hexagon shaped plate 20 and a plurality of gaps 22 disposed between adjacent hexagon shaped plates 20. The second substrate 24 may be formed on the first surface 14 of the first substrate 12 via printing. The hexagon pattern 18 may have a high area fill fraction that may accommodate for improved heat transfer of the metal-clad substrate 10. Additionally, the plurality of gaps 22 may provide contiguous pathways between adjacent hexagon shaped plates 20 to facilitate outgassing during high temperature processing and may additionally provide intrinsic strain relief via expansion joints.

The combination of the concentric-circle pattern 16 on the first surface 14 and the hexagon pattern 18 of at least one hexagon shaped plate 20 may produce an interconnect or interfacial boundary which maximizes heat transfer, sheer strength, and thermal cycling resistance of the metal-clad substrate 10. The metal-clad substrate 10 may be a large area electronic device, that is, an electronic device having a surface area of approximately 1-3 square centimeters. The combination of the concentric-circle pattern 16 formed on the first surface 14 and the hexagon pattern 18 on at least one hexagon shaped plate 20 may enable more efficient and inexpensive thermal management of power electronic devices while simultaneously producing improved device reliability.

An individual hexagon shaped plate 20 of the at least one hexagon shaped plate 20 may have a surface area ranging from about 80 to about 90 square millimeters. The at least one hexagon shaped plate 20 may also have a surface area of about 86 square millimeters, or about 86.62 square millimeters.

The plurality of gaps 22 may include at least one individual gap that may be approximately 0.6 to about 0.40 millimeters in width. Each individual gap may also be about 0.50 millimeters in width. In this way, the hexagon pattern 18 may include at least one hexagon shaped plate 20 separated from adjacent hexagon shaped plates 20 by a plurality of gaps 22 such that the first surface 14 of the first substrate 12 is completely covered in the hexagon pattern 18 of hexagon shaped plates 20.

In practice and in use, the first substrate may be formed, mechanically or chemically machined, or etched to provide for the concentric-circle pattern that may include radial or concentric corrugation and may be overlaid with the second substrate 24 via a printing process, deposition process, or other similar cladding process such that the first substrate 12 and the second substrate 24 form a metal-clad substrate 10. The second substrate 24 may include a sinterable silver paste. The first substrate 12 may include a metallic or ceramic material. The metal-clad substrate may be an electronic device or a portion of an electronic device.

According to variation 1, a product may include a first substrate having at least one concentrically ground surface and a second substrate overlying the first substrate in a hexagonally-arrayed print pattern.

Variation 2 may include a product as set forth in variation 1, wherein the first substrate may include a metal material.

Variation 3 may include a product as set forth in variations 1 or 2, wherein the first substrate may include a ceramic material.

Variation 4 may include a product as set forth in any of variations 1-3, wherein the second substrate may include a metal material.

Variation 5 may include a product as set forth in variation 4, wherein the metal material may be a sinterable silver paste.

Variation 6 may include a product as set forth in any of variations 1-5, wherein the hexagonally-arrayed print pattern may include a plurality of hexagon shaped plates and a plurality of gaps, wherein the gaps may be disposed between adjacent hexagon shaped plates such that each hexagon shaped plate may not be in contact with adjacent hexagon shaped plates.

Variation 7 may include a product as set forth in any of variations 1-6, wherein the plurality of hexagon shaped plates may include at least a first hexagon shaped plate having a surface area ranging from about 80 to about 90 square millimeters.

Variation 8 may include a product as set forth in any of variations 1-6, wherein the plurality of hexagon shaped plates may include at least a first hexagon shaped plate having a surface area of about 86.6 square millimeters.

Variation 9 may include a product as set forth in any of variations 6-8, wherein the plurality of gaps may range from about 0.6 to about 0.4 millimeters in width.

Variation 10 may include a product as set forth in any of variations 6-9, wherein the plurality of gaps may be about 0.5 millimeters in width.

According to variation 11, a method may include providing a first substrate that may include first surface and a first material; grinding the first surface of the first substrate in a concentric-circle pattern that may include radial corrugation channels; and cladding the first surface of the first substrate with a second material by forming a hexagonal pattern of the second material on the first surface.

Variation 12 may include a method as set forth in variation 11, and may further include sintering the second material to form an interconnect between the first material and the second material.

Variation 13 may include a method as set forth in any of variations 11-12, wherein cladding the first surface of the first substrate with a second material may include printing.

Variation 14 may include a method as set forth in any of variations 11-13, wherein the first material may include a metal.

Variation 15 may include a method as set forth in variations 11-14, wherein the first material may include a ceramic.

Variation 16 may include a method as set forth in variations 11-15, wherein the second material may include a metal.

Variation 17 may include a method as set forth in any of variations 11-16, wherein the second material may be a sinterable silver paste.

Variation 18 may include a method as set forth in variations 11-17, wherein the hexagonal pattern may include at least a first hexagon shaped plate having a surface area ranging from about 80 to about 90 square millimeters.

Variation 19 may include a method as set forth in any of variations 11-18, wherein the hexagonal pattern may include at least a first hexagonal shaped plate having a surface area of about 86.6 square millimeters.

According to variation 20 a method may include providing a first substrate that may include a first surface and a first material; grinding the first surface of the first substrate in a concentric-circle pattern that may include radial corrugation channels. The method may further include cladding the first surface of the first substrate with a second material that may include sinterable silver paste by printing a hexagonal pattern of the second material on the first surface wherein the hexagonal pattern may include a plurality of hexagon shaped plates that may each have a surface area of about 86 square millimeters and wherein a plurality of gaps may be disposed between adjacent hexagon shaped plates, the gaps each being about 0.5 millimeters in width. The method may further include sintering the second material to form an interconnect between the first material and the second material.

The above description of variations of the invention is merely demonstrative in nature and, thus, variations thereof are not to be regarded as a departure from the spirit and scope of the inventions disclosed within this document.

1. A product comprising:
a first substrate having at least one concentrically ground surface; and
a second substrate overlying the first substrate in a hexagonally-arrayed print pattern.

2. A product as set forth in claim 1, wherein the first substrate comprises a metal material.

3. A product as set forth in claim 1, wherein the first substrate comprises a ceramic material.

4. A product as set forth in claim 1, wherein the second substrate comprises a metal material.

5. A product as set forth in claim 4, wherein the metal material is a sinterable silver paste.

6. A product as set forth in claim 1, wherein the hexagonally-arrayed print pattern comprises a plurality of hexagon shaped plates and a plurality of gaps, the gaps being disposed between adjacent hexagon shaped plates such that each hexagon shaped plate is not in contact with any adjacent hexagon shaped plates.

7. A product as set forth in claim 6, wherein the plurality of hexagon shaped plates comprises at least a first hexagon shaped plate having a surface area ranging from about 80 to about 90 square millimeters.

8. A product as set forth in claim 6, wherein the plurality of hexagon shaped plates comprises at least a first hexagon shaped plate having a surface area of about 86.6 square millimeters.

9. A product as set forth in claim 6, wherein the plurality of gaps range from about 0.6 to about 0.4 millimeters in width.

10. A product as set forth in claim 6, wherein the plurality of gaps are about 0.5 millimeters in width.

11. A method comprising:
providing a first substrate comprising a first surface and a first material;
grinding the first surface of the first substrate to provide a concentric-circle pattern comprising radial corrugation channels; and
cladding the first surface of the first substrate with a second material by forming a hexagonal pattern of the second material on the first surface.

12. A method as set forth in claim 11, further comprising:
sintering the second material to form an interconnect between the first material and the second material.

13. A method as set forth in claim 11, wherein cladding the first surface of the first substrate with a second material comprises printing.

14. A method as set forth in claim 11, wherein the first material comprises a metal.

15. A method as set forth in claim 11, wherein the first material comprises a ceramic.

16. A method as set forth in claim 11, wherein the second material comprises a metal.

17. A method as set forth in claim 16, wherein the second material is a sinterable silver paste.

18. A method as set forth in claim 11, wherein the hexagonal pattern comprises at least a first hexagon shaped plate having a surface area ranging from about 80 to about 90 square millimeters.

19. A method as set forth in claim 11, wherein the hexagonal pattern comprises at least a first hexagon shaped plate having a surface area of about 86.6 square millimeters.

20. A method comprising:
providing a first substrate comprising a first surface and a first material,
grinding the first surface of the first substrate to provide a concentric-circle pattern comprising radial corrugation channels;
cladding the first surface of the first substrate with a second material comprising a sinterable silver paste by printing a hexagonal pattern of the second material on the first surface wherein the hexagonal pattern comprises a plurality of hexagon shaped plates each having a surface area of about 86 square millimeters and wherein a plurality of gaps are each disposed between adjacent hexagon shaped plates and are about 0.5 millimeters in width; and
sintering the second material to form an interconnect between the first material and the second material.
